(19) United States
(12) Patent Application Publication
(10) Pub. No.: US 2026/0182120 A1
(43) Pub. Date: Jun. 25, 2026

(54) DISPLAY APPARATUS AND METHOD OF MANUFACTURING THE SAME

(71) Applicant: Samsung Electronics Co., Ltd., Suwon-si (KR)

(72) Inventors: Soonmin HONG, Suwon-si (KR); Yeonghyeon SEO, Suwon-si (KR); Changsun KANG, Suwon-si (KR); Hosuk KANG, Suwon-si (KR); Changman LIM, Suwon-si (KR); Youngmin CHO, Suwon-si (KR)

(21) Appl. No.: 19/542,376

(22) Filed: Feb. 17, 2026

Related U.S. Application Data
(63) Continuation of application No. PCT/KR2025/018106, filed on Nov. 6, 2025.

(30) Foreign Application Priority Data
Nov. 15, 2024 (KR) 10-2024-0163604

(51) Int. Cl. H10H 29/80; H10H 29/01

(52) U.S. Cl. CPC H10H 29/8421; H10H 29/034

(57) ABSTRACT

A display apparatus includes: a substrate; a first electrode layer disposed on the substrate; a second electrode layer disposed on or above the first electrode layer and including a transparent electrode; an emission layer disposed between the first electrode layer and the second electrode layer, and including a plurality of vertical-type light-emitting elements; and an anti-reflection layer disposed on the second electrode layer.

### CROSS-REFERENCES TO RELATED APPLICATIONS

This application is a continuation of International Application No. PCT/KR2025/018106 designating the United States, filed on Nov. 6, 2025, in the Korean Intellectual Property Receiving Office and claiming priority to Korean Patent Application No. 10-2024-0163604, filed on Nov. 15, 2024, in the Korean Intellectual Property Office, the disclosures of each of which are incorporated by reference herein in their entireties.

### BACKGROUND

### Field

The disclosure relates to a display apparatus including a vertical light-emitting element and a method of manufacturing the display apparatus.

### Description of Related Art

Display apparatuses may be classified into self-emissive displays where each pixel emits light by itself, and light-receiving displays that require a separate light source.

In a self-emissive display in which each pixel includes a light-emitting element and emits light by itself, components such as a backlight unit and a liquid crystal layer are not required, and even a color filter may be omitted. Accordingly, the structure may be simplified, allowing for high design flexibility. Furthermore, a slim thickness, excellent contrast ratio, high brightness, and wide viewing angle may be achieved.

Among self-emissive displays, a micro light emitting diode (LED) display includes a plurality of micro-sized LEDs. Compared to a liquid crystal display (LCD) that requires a backlight, a micro LED display may provide superior contrast, faster response time, and higher energy efficiency.

LEDs may be classified into horizontal-type LEDs, vertical-type LEDs, and flip-chip LEDs according to their structure.

In the case of vertical-type LEDs, the P-type electrode and the N-type electrode are arranged vertically, allowing the LED to be implemented in a relatively small size while achieving high light output relative to its size. Accordingly, research on such structures is actively underway.

### SUMMARY

Embodiments of the disclosure provide a display apparatus including a transparent electrode configured to electrically connect a plurality of vertical-type light-emitting elements and an anti-reflection layer configured to adjust reflective characteristics, as well as a method for controlling the display apparatus.

According to an example embodiment of the disclosure, a display apparatus may include: a substrate; a first electrode layer disposed on the substrate; a second electrode layer disposed on or above the first electrode layer and including a transparent electrode; an emission layer disposed between the first electrode layer and the second electrode layer, and including a plurality of vertical-type light-emitting elements; and an anti-reflection layer disposed on or above the second electrode layer.

The anti-reflection layer may have a first thickness in a vertical direction of the substrate and have a first refractive index, the second electrode layer may have a second thickness in the vertical direction of the substrate and have a second refractive index, and wherein the first thickness may be determined based on the first refractive index, the second thickness, and the second refractive index.

The first thickness may be determined based on Equation 1 or Equation 2 below:

$${d}_{1} = \frac{{n}_{2} {d}_{2}}{2 {n}_{1} ( m - \frac{1}{2} )} \qquad [ Equation 1 ]$$

(d₁ is the first thickness, n₁ is the first refractive index, n₂ is the second refractive index, d₂ is the second thickness, and m is 1, 2, or 3.)

$${d}_{1} = \frac{{n}_{2} {d}_{2}}{2 {n}_{1} m} \qquad [ Equation 2 ]$$

(d₁ is the first thickness, n₁ is the first refractive index, n₂ is the second refractive index, d₂ is the second thickness, and m is 1, 2, or 3.)

Based on a refractive index of the emission layer being less than the second refractive index, the first thickness may be determined based on Equation 1.

Based on a refractive index of the emission layer being greater than the second refractive index, the first thickness may be determined based on Equation 2.

The anti-reflection layer may be directly stacked on the second electrode layer.

The emission layer may further include a connector configured to electrically connect the transparent electrode and the first electrode layer, the first electrode layer may include at least one anode in electrical contact with a first electrode of each of the plurality of vertical-type light-emitting elements and at least one cathode in electrical contact with the connector, and the transparent electrode may be in electrical contact with a second electrode of each of the plurality of vertical-type light-emitting elements.

The connector may include a first connector electrode in electrical contact with the transparent electrode and a second connector electrode in electrical contact with the at least one cathode.

According to an example embodiment of the disclosure, in a method of manufacturing a display apparatus, the method may include: forming a first electrode layer on a substrate; forming an emission layer on the first electrode layer, the emission layer including a plurality of vertical-type light-emitting elements; forming a second electrode layer on the emission layer, the second electrode layer including a transparent electrode; and forming an anti-reflection layer on the second electrode layer.

The forming of the anti-reflection layer on the second electrode layer may include forming the anti-reflection layer to have a first thickness in a vertical direction of the substrate, the forming of the second electrode layer on the emission layer may include forming the second electrode layer to have a second thickness in the vertical direction of the substrate, the anti-reflection layer may have a first refractive index, the second electrode layer may have a second refractive index, and the first thickness may be determined based on the first refractive index, the second thickness, and the second refractive index.

The first thickness may be determined based on Equation 1 or Equation 2 below.

$${d}_{1} = \frac{{n}_{2} {d}_{2}}{2 {n}_{1} ( m - \frac{1}{2} )} \qquad [ Equation 1 ]$$

(d₁ is the first thickness, n₁ is the first refractive index, n₂ is the second refractive index, d₂ is the second thickness, and m is 1, 2, or 3.)

$${d}_{1} = \frac{{n}_{2} {d}_{2}}{2 {n}_{1} m} \qquad [ Equation 2 ]$$

(d₁ is the first thickness, n₁ is the first refractive index, n₂ is the second refractive index, d₂ is the second thickness, and m is 1, 2, or 3.)

Based on a refractive index of the emission layer being less than the second refractive index, the first thickness may be determined based on Equation 1.

Based on a refractive index of the emission layer being greater than the second refractive index, the first thickness may be determined based on Equation 2.

The forming of the second electrode layer on the emission layer and the forming of the anti-reflection layer on the second electrode layer may include: selecting a thickness of the anti-reflection layer as a first thickness and a thickness of the second electrode layer as a second thickness to implement a first color as a reflective color of the display apparatus; and selecting the thickness of the anti-reflection layer as the first thickness and the thickness of the second electrode layer as a third thickness, different from the second thickness, to implement a second color different from the first color as the reflective color of the display apparatus.

The forming of the second electrode layer on the emission layer and the forming of the anti-reflection layer on the second electrode layer may include: selecting a thickness of the anti-reflection layer as a first thickness and a thickness of the second electrode layer as a second thickness to implement a first color as a reflective color of the display apparatus; and selecting the thickness of the anti-reflection layer as a third thickness, different from the first thickness, and the thickness of the second electrode layer as the second thickness to implement a second color different from the first color as the reflective color of the display apparatus.

The forming of the second electrode layer on the emission layer and the forming of the anti-reflection layer on the second electrode layer may include: selecting a thickness of the anti-reflection layer as a first thickness and a thickness of the second electrode layer as a second thickness to implement a first color as a reflective color of the display apparatus; and selecting the thickness of the anti-reflection layer as a third thickness, different from the first thickness, and the thickness of the second electrode layer as a fourth thickness different from the second thickness to implement a second color different from the first color as the reflective color of the display apparatus.

The forming of the anti-reflection layer on the second electrode layer may include determining a material of the anti-reflection layer based on a refractive index of the second electrode layer.

The determining of the material of the anti-reflection layer may include determining the material of the anti-reflection layer to have a refractive index which having a value determined according to the refractive index of the second electrode layer.

The forming of the first electrode layer on the substrate may include laminating an adhesive film on the substrate, and the forming of the emission layer on the first electrode layer may include attaching or transferring the plurality of vertical-type light-emitting elements and a connector to the substrate on which the adhesive film is laminated, the connector being configured to electrically connect the transparent electrode and the first electrode layer.

The forming of the anti-reflection layer on the second electrode layer may include: directly stacking the anti-reflection layer on the second electrode layer, and may further include forming an optical film on the anti-reflection layer.

According to the disclosure, thin-film interference that may be caused by a transparent electrode configured to electrically connect a plurality of vertical-type light-emitting elements may be prevented and/or reduced.

According to the disclosure, a reflectance of light that has passed through the display apparatus may be reduced.

According to the disclosure, various reflective colors of light passing through the display apparatus may be implemented by adjusting the thicknesses of the transparent electrode and the anti-reflection layer.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a perspective view illustrating an example of a display module and a display apparatus including the same according to various embodiments;

FIG. 2 is a diagram illustrating an example of a pixel array including a unit module of a display apparatus according to various embodiments;

FIG. 3 is an enlarged cross-sectional view of a side portion of a display apparatus according to various embodiments;

FIGS. 4 and 5 are diagrams illustrating an example process in which light passing through the display apparatus is reflected, according to various embodiments

FIG. 6 is a table illustrating reflective colors of light passing through the display apparatus according to thicknesses of an anti-reflection layer and a transparent electrode, according to various embodiments;

FIG. 7 is a flowchart illustrating an example method of manufacturing a display apparatus according to various embodiments;

FIG. 8 includes cross-sectional views illustrating an example method of manufacturing a display apparatus according to various embodiments;

FIG. 9 is an enlarged cross-sectional view of a side portion of a display apparatus according to various embodiments; and

FIGS. 10 and 11 are cross-sectional views illustrating an example in which a transparent electrode is in electrical contact with a cathode according to various embodiments.

### DETAILED DESCRIPTION

Various embodiments and the terms used therein are not intended to limit the disclosure to specific forms, and the disclosure should be understood to include various modifications, equivalents, and/or alternatives.

In describing the drawings, similar reference numerals may be used to designate similar elements.

A singular expression may include a plural expression unless otherwise indicated herein or clearly contradicted by context.

The expressions “A or B,” “at least one of A or/and B,” or “one or more of A or/and B,” A, B or C,” “at least one of A, B or/and C,” or “one or more of A, B or/and C,” and the like used herein may include any and all combinations of one or more of the associated listed items.

The term of “and/or” includes a plurality of combinations of relevant items or any one item among a plurality of relevant items.

The terms such as “˜portion”, “˜member”, “˜module”, and the like may be implemented in hardware or software. According to embodiments, a plurality of “˜portions”, “˜members”, or “˜modules” may be embodied as a single element, or a single “˜portion”, “˜member”, or “˜module” may include a plurality of elements.

Herein, the expressions “a first”, “a second”, “the first”, “the second”, etc., may simply be used to distinguish an element from other elements, but is not limited to another aspect (e.g., importance or order) of elements.

When an element (e.g., a first element) is referred to as being “(functionally or communicatively) coupled,” or “connected” to another element (e.g., a second element), the first element may be connected to the second element, directly (e.g., wired), wirelessly, or through a third element.

In this disclosure, the terms “including”, “having”, and the like are used to specify features, numbers, steps, operations, elements, components, or combinations thereof, but do not preclude the presence or addition of one or more of the features, elements, steps, operations, elements, components, or combinations thereof.

When an element is said to be “connected”, “coupled”, “supported” or “contacted” with another element, this includes not only when elements are directly connected, coupled, supported or contacted, but also when elements are indirectly connected, coupled, supported or contacted through a third element.

Throughout the description, when an element is referred to as being “on” or “above” another element, this includes not only when the element is in contact with the other element, but also when there is another element between the two elements.

The terms “front”, “rear”, “left”, “right”, “upper”, and “lower” used in the following description are defined based on the drawings, and the shape and location of each component are not limited by these terms. For example, the front side may be defined as the +X side and the rear side may be defined as the −X side. For example, based on the drawings, the right side may be defined as the +Y side and the left side may be defined as the −Y side. For example, based on the drawings, the upper side may be defined as the +Z side and the lower side may be defined as the −Z side.

Hereinafter, various example embodiments of the disclosure will be described in greater detail with reference to the accompanying drawings.

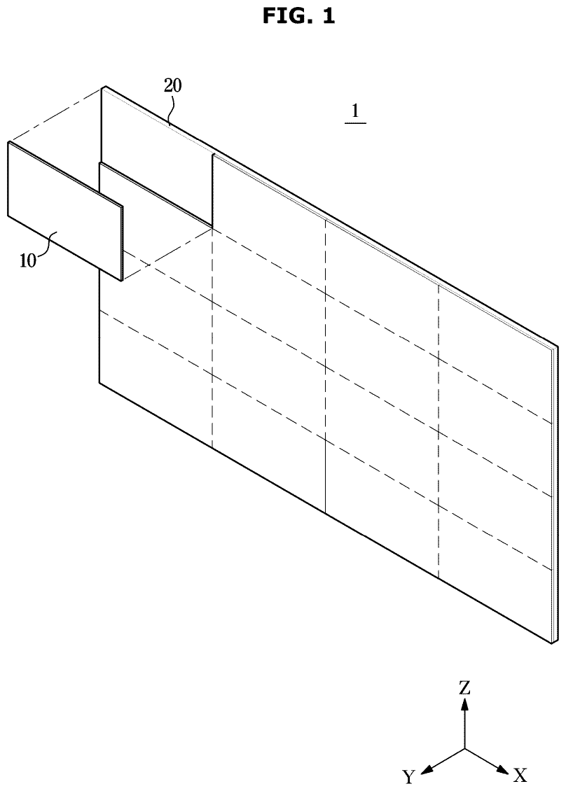

FIG. 1 is a perspective view illustrating an example display module and a display apparatus including the same according to various embodiments.

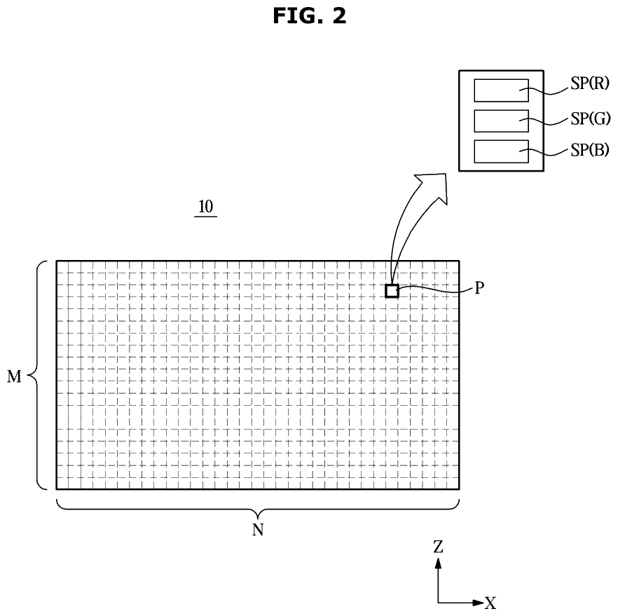

FIG. 2 is a diagram illustrating an example pixel array including a unit module of a display apparatus according to various embodiments.

According to an embodiment, the display apparatus may include a self-emissive display apparatus in which each pixel includes a light-emitting element and emits light by itself. Accordingly, the display apparatus does not require components such as a backlight unit or a liquid crystal layer, and thus may be made thinner and structurally simpler, allowing for a wider range of design variations.

The light-emitting elements arranged in each pixel of the display apparatus according to an embodiment may include inorganic light-emitting elements such as inorganic light-emitting diodes (LEDs). Inorganic LEDs have faster response speeds and may achieve high luminance with low power consumption compared to organic light-emitting diodes (OLEDs).

Furthermore, unlike organic light-emitting elements, which require encapsulation due to their vulnerability to moisture and oxygen and have relatively low durability, inorganic light-emitting elements do not require encapsulation and are more durable. In the disclosure, the term “inorganic light-emitting element” refers to an inorganic LED.

The inorganic light-emitting elements employed in the display apparatus may include micro-LEDs having a short side length of approximately 100 μm, several tens of micrometers, or even a few micrometers. Using micro-scale LEDs, the pixel size may be reduced, enabling high resolution even within the same screen size.

Micro-sized LED chips, due to the characteristics of inorganic materials, are less prone to breakage when bent. For example, when micro-LED chips are transferred onto a flexible substrate, the micro-LED chips are less likely to crack, even when the substrate is bent, thereby enabling the implementation of flexible display apparatuses.

A display apparatus employing micro-LEDs may be applied to various fields utilizing ultra-small pixel sizes and thin thickness. For example, as shown in FIG. 1, a large-area display screen may be implemented by tiling and fixing a plurality of display modules 10, each having transferred micro-LEDs, onto a main body 20. Such a large-area display apparatus 1 may be used as signage or an electronic billboard.

The three-dimensional XYZ coordinate system shown in FIG. 1 is defined with respect to the display apparatus 1. The plane in which the screen of the display apparatus 1 lies corresponds to the XZ plane, and the direction in which the image is output, or the light-emitting direction of the inorganic light-emitting elements, is the +Y direction. Because the coordinate system is defined relative to the display apparatus 1, the coordinate system may be consistently applied regardless of whether the display apparatus 1 is laid flat or stood upright.

Generally, the display apparatus 1 is used in an upright position, and a user views the image from the front of the display apparatus 1. Therefore, the +Y direction, in which the image is output, may be referred to as the front side, and the opposite direction as the rear side.

The display apparatus 1 may typically be manufactured in a horizontal position. Thus, the −Y direction may be referred to as the lower side, and the +Y direction as the upper side. In other words, in the following embodiments, the +Y direction may be referred to as the upper side or the front side, and the −Y direction may be referred to as the lower side or the rear side.

Except for the upper and lower sides of the flat display apparatus 1 or the display module 10, the remaining four sides are collectively referred to as side surfaces, regardless of the orientation of the display apparatus 1 or the display module 10.

Although the example shown in FIG. 1 illustrates a case in which the display apparatus 1 implements a large-area screen by including a plurality of display modules, the disclosure is not limited thereto. The display apparatus 1 may also include a single display module 10 and be implemented as a television (TV), wearable device, portable device, or personal computer (PC) monitor.

Referring to FIG. 2, the display module 10 may include an M×N (where M and N are integers greater than or equal to 2) array of pixels, e.g., a plurality of pixels arranged in two dimensions. FIG. 2 conceptually illustrates the pixel array, and it is understood that regions such as a bezel or wiring area in which images are not displayed may also be present in the display module 10 in addition to the active area where pixels are arranged.

In an embodiment, components described as being arranged in two dimensions may include cases in which the components are arranged on the same plane as well as on different, parallel planes. Even when components are arranged on the same plane, the upper ends of the components may not lie on the same plane. The upper ends of the components may be on different, parallel planes.

Each pixel P may include a plurality of sub-pixels that emit light of different colors to implement various colors by color combination. For example, a pixel P may include at least three sub-pixels emitting light of different colors. Specifically, the pixel P may include three sub-pixels SP R, SP G, and SP B corresponding to red, green, and blue, respectively. The red sub-pixel SP R may emit red light, the green sub-pixel SP G may emit green light, and the blue sub-pixel SP B may emit blue light.

However, the pixel array shown in FIG. 2 is merely an example applicable to the display module 10 and the display apparatus 1. The sub-pixels may be arranged in the X-axis direction, or non-linearly, and their sizes may differ. A single pixel may include a plurality of sub-pixels to represent various colors, and the size or arrangement method of the sub-pixels are not limited.

Each pixel P does not necessarily have to include red, green, and blue sub-pixels, and sub-pixels emitting yellow or white light may be included. Thus, it will be understood that the number, color, and type of light emitted by each sub-pixel are not limited.

However, for ease of description and understanding, the disclosure illustrates an example in which a pixel P includes a red sub-pixel SP R, a green sub-pixel SP G, and a blue sub-pixel SP B.

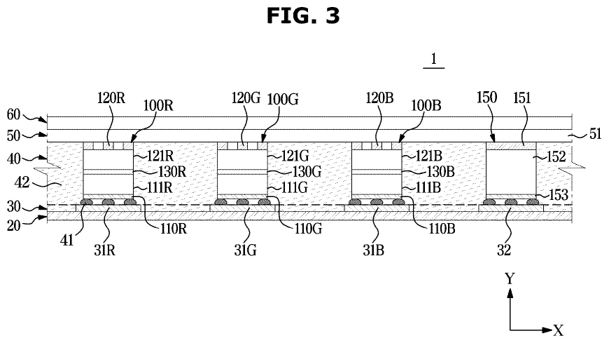

As previously described, the display module 10 and the display apparatus 1 according to an embodiment includes self-emissive displays in which each pixel emits light by itself. Accordingly, each sub-pixel may include an inorganic light-emitting element that emits light of a different color. For example, a red vertical-type light-emitting element 100R (see FIG. 3) may be arranged in the red sub-pixel SP R, a green vertical-type light-emitting element 100G (see FIG. 3) may be arranged in the green sub-pixel SP G, and a blue inorganic light-emitting element 100B (see FIG. 3) may be arranged in the blue sub-pixel SP B.

Thus, the pixel P according to the disclosure may represent a cluster including the red vertical-type light-emitting element 100R, the green vertical-type light-emitting element 100G, and the blue inorganic light-emitting element 100B (see FIG. 3), and each sub-pixel may represent each vertical-type light-emitting element.

Hereinafter, the following description will be provided with reference to the display apparatus 1, but is equally applicable to each of the plurality of display modules 10 of the display apparatus 1.

FIG. 3 is an enlarged cross-sectional view illustrating a side of a display apparatus according to various embodiments.

Referring to FIG. 3, a display apparatus 1 according to an embodiment may include a substrate 20.

The upper side of the substrate 20 may correspond to the +Y direction, and the lower side may correspond to the −Y direction.

Various components, such as a plurality of vertical-type light-emitting elements 100R, 100G, and 100B, may be disposed on the substrate 20.

The substrate 20 may be formed of various materials. For example, the substrate 20 may be formed of transparent glass mainly made of SiO2, a flexible transparent plastic, or a metal.

Although not illustrated in FIG. 3, the substrate 20 may include a glass substrate, a buffer layer provided on the upper side of the glass substrate to provide a planar surface, and a thin film transistor (TFT) formed on the buffer layer for supplying a driving current to the plurality of vertical-type light-emitting elements 100R, 100G, and 100B.

The display apparatus 1 may include a first electrode layer 30 provided on the substrate 20.

The first electrode layer 30 may include a plurality of electrodes.

For example, the first electrode layer 30 may include at least one anode and at least one cathode.

The at least one anode may include a first anode 31R, a second anode 31G, and/or a third anode 31B.

The first anode 31R may deliver a driving current supplied from the TFT included in the substrate 20 to the red vertical-type light-emitting element 100R.

The second anode 31G may deliver a driving current from the TFT to the green vertical-type light-emitting element 100G.

The third anode 31B may deliver a driving current from the TFT to the blue vertical-type light-emitting element 100B.

The first, second, and third anodes may be referred to collectively as anodes.

The at least one anode may be configured as a single electrode or as a plurality of electrodes. In the following description, it is assumed to include a plurality of anodes 31R, 31G, and 31B.

The at least one cathode 32 may be an electrode from which the driving current flowing through the vertical-type light-emitting elements 100R, 100G, and 100B flows out.

The at least one cathode 32 may be referred to as a cathode.

The cathode 32 may be configured as a common electrode electrically connected to the plurality of anodes 31R, 31G, and 31B.

The at least one cathode 32 may be configured as a single electrode or as a plurality of electrodes. In the following description, it is assumed to include a single cathode 32.

The display apparatus 1 may include an emission layer 40 provided on the first electrode layer 30.

The emission layer 40 may include the vertical-type light-emitting elements 100R, 100G, and 100B.

The vertical-type light-emitting elements 100R, 100G, and 100B may include the red vertical-type light-emitting elements 100R, the green vertical-type light-emitting elements 100G, and the blue vertical-type light-emitting elements 100B.

The vertical-type light-emitting elements 100R, 100G, and 100B may include a first semiconductor layer 111R, 111G, and 111B, respectively.

The first semiconductor layers 111R, 111G, and 111B may be a p-type semiconductor layer. For example, the first semiconductor layers 111R, 111G, and 111B may be a p-GaN layer doped with a p-type material.

The vertical-type light-emitting elements 100R, 100G, and 100B may include a first electrode 110R, 110G, and 110B provided below the first semiconductor layer, respectively.

Each of the first electrodes 110R, 110G, and 110B may be electrically in contact with the first semiconductor layer.

Each of the first electrodes 110R, 110G, and 110B may be a p-type electrode.

The first electrodes 110R, 110G, and 110B may be in electrical contact with the anodes 31R, 31G, and 31B.

The first electrodes 110R, 110G, and 110B may be in electrical contact with the anodes 31R, 31G, and 31B to allow the driving current supplied from the anodes 31R, 31G, and 31B to flow into the first semiconductor layers 111R, 111G, and 111B.

The vertical-type light-emitting elements 100R, 100G, and 100B may include a second semiconductor layer 121R, 121G, and 121B disposed on the first semiconductor layers 111R, 111G, and 111B, respectively.

The second semiconductor layers 121R, 121G, and 121B may be an n-type semiconductor layer, such as an n-GaN layer doped with an n-type material.

Each of the first semiconductor layers 111R, 111G, and 111B and the second semiconductor layers 121R, 121G, and 121B may be vertically arranged with respect to the substrate 20.

For example, the first semiconductor layers 111R, 111G, and 111B and the second semiconductor layers 121R, 121G, and 121B may be arranged in the +Y direction, which is the vertical direction of substrate 20.

The vertical-type light-emitting elements 100R, 100G, and 100B may include an active layer 130R, 130G, and 130B disposed between the first semiconductor layers 111R, 111G, and 111B and the second semiconductor layers 121R, 121G, and 121B, respectively.

The active layers 130R, 130G, and 130B may be light-emitting layer in which electrons and holes recombine to emit light.

The vertical-type light-emitting elements 100R, 100G, and 100B may include a second electrode 120R, 120G, and 120B provided on the second semiconductor layers 121R, 121G, and 121B, respectively.

The second electrodes 120R, 120G, and 120B may be an n-type electrode.

The second electrodes 120R, 120G, and 120B may be electrically in contact with a transparent electrode 51.

The second electrodes 120R, 120G, and 120B may be configured in plurality. For example, the second electrodes 120R, 120G, and 120B may be respectively disposed at the edge and center portions of each of the vertical-type light-emitting elements 100R, 100G, and 100B.

The second electrodes 120R, 120G, and 120B may be smaller in size than the first electrodes 110R, 110G, and 110B. However, the size of the second electrode may also be larger than or equal to that of the first electrode.

Although the first electrodes 110R, 110G, and 110B are described as p-type electrodes and the second electrodes 120R, 120G, and 120B as n-type electrodes, in various embodiments, the first electrodes may be n-type electrodes and the second electrodes may be p-type electrodes. In that case, the first semiconductor layers 111R, 111G, and 111B may be n-type semiconductor layers and the second semiconductor layers 121R, 121G, and 121B may be p-type semiconductor layers.

In the following description, the first electrodes 110R, 110G, and 110B are assumed to be p-type electrodes, and the second electrodes 120R, 120G, and 120B are assumed to be n-type electrodes.

The first electrodes 110R, 110G, and 110B and the second electrodes 120R, 120G, and 120B may be arranged in the vertical direction with respect to substrate 20.

For example, the light-emitting elements according to the disclosure may be vertical-type light-emitting elements.

Unlike lateral-type or flip-type light-emitting elements, in which different electrodes (e.g., n-type and p-type electrodes) are arranged in the horizontal direction with respect to the substrate, in vertical-type light-emitting elements, the different electrodes are arranged in the vertical direction with respect to the substrate, enabling a relatively small size of the light-emitting element and high output.

The emission layer 40 may include a connector 150 for electrically connecting the transparent electrode 51 and the first electrode layer 30. For example, the connector 150 may electrically connect the transparent electrode 51 and the cathode 32.

For example, the connector 150 may include a first connector electrode 151 in electrical contact with the transparent electrode 51 and a second connector electrode 152 in electrical contact with the cathode 32. The connector 150 may further include a connector semiconductor layer 153 disposed between the first connector electrode 151 and the second connector electrode 152.

Accordingly, the transparent electrode 51 and the cathode 32 may be electrically connected.

The emission layer 40 may include an adhesive film 42. The adhesive film 42 may include a conductive adhesive film. For example, the adhesive film 42 may be an anisotropic conductive film (ACF). However, the material of adhesive film 42 is not limited thereto. For example, the adhesive film 42 may be a non-conductive film (NCF).

The adhesive film 42 may be a black anisotropic conductive film (Black ACF) made of a black polymer resin.

The adhesive film 42 may also be a black non-conductive film (Black NCF) made of a black polymer resin.

A portion of the first electrode layer 30 may also be formed of the adhesive film 42.

The adhesive film 42 may allow for an electrical connection in the vertical direction (Y direction) of the substrate 20, but may be insulating in the horizontal direction (X direction) of substrate 20. The adhesive film 42 may include conductive media or a conductive material. For example, the adhesive film 42 may include conductive balls. For example, the adhesive film 42 may be in the form of a film in which conductive balls are mixed into an insulating base member. When heat and pressure are applied, only specific portions (e.g., portions where the vertical-type light-emitting elements 100R, 100G, and 100B and the at least one anode 31R, 31G, or 31B are in contact) may be rendered conductive by the conductive balls.

The conductive media of the adhesive film 42 may vary.

For example, in a case where the adhesive film 42 is a non-conductive film (NCF), the conductive media may include elastic bumps or nano carbon.

The elastic bumps may be conductive projections having a size of approximately 1 to 3 μm and elasticity. Nano carbon may be a conductive material in which carbon particles of nanometer size are mixed with resin.

The display apparatus 1 according to an embodiment may include a second electrode layer 50 provided on the first electrode layer 30. For example, the second electrode layer 50 may be provided on the first electrode layer 30, and the emission layer 40 may be disposed between the first electrode layer 30 and the second electrode layer 50.

The display apparatus 1 according to an embodiment may include the second electrode layer 50 provided on the emission layer 40.

The second electrode layer 50 may include the transparent electrode 51. The transparent electrode 51 may be made of Indium Tin Oxide (ITO), Indium Zinc Oxide (IZO), nano wire paste, and the like. The transparent electrode 51 may have transparency and conductivity.

The transparent electrode 51 may electrically connect the vertical-type light-emitting elements 100R, 100G, and 100B. For example, the transparent electrode 51 may be in electrical contact with and be electrically connected to the second electrodes 120R, 120G, and 120B of the vertical-type light-emitting elements 100R, 100G, and 100B.

The transparent electrode 51 may be in electrical contact with the first connector electrode 151 of the connector 150 to electrically connect the vertical-type light-emitting elements 100R, 100G, and 100B and the first connector electrode 151 of the connector 150.

The display apparatus 1 may include an anti-reflection layer 60 provided on the second electrode layer 50.

The anti-reflection layer 60 may be formed of a transparent material. For example, the anti-reflection layer 60 may include silicon dioxide (SiO₂), magnesium fluoride (MgF₂), aluminum oxide (Al₂O₃), titanium dioxide (TiO₂), or zirconium dioxide (ZrO₂).

The anti-reflection layer 60 according to an embodiment may be directly stacked on the second electrode layer 50.

Directly stacking may indicate that no other component is disposed between the anti-reflection layer 60 and the second electrode layer 50, and the anti-reflection layer 60 and the second electrode layer 50 are in contact with each other.

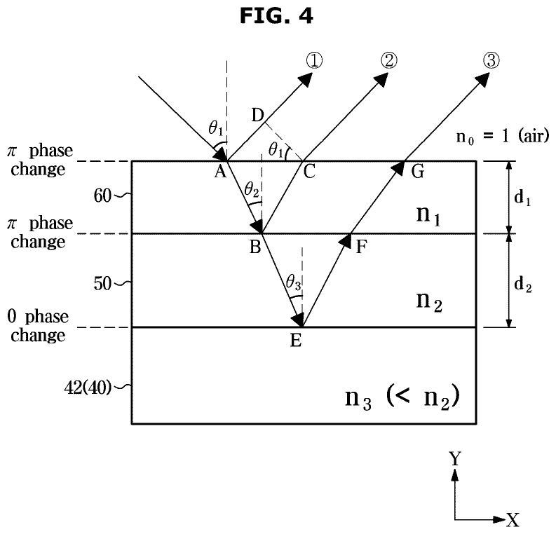

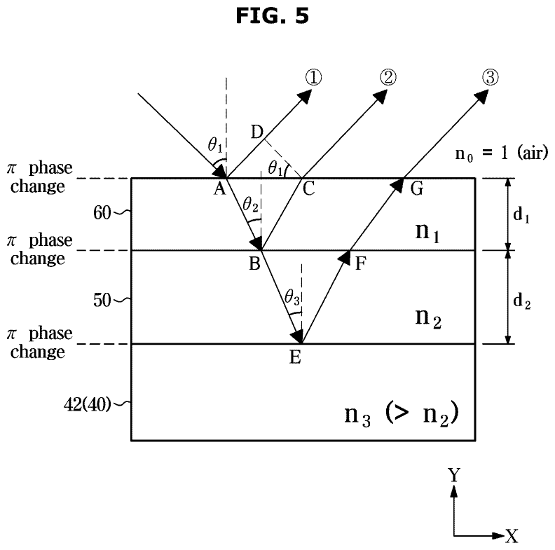

FIGS. 4 and 5 are diagrams illustrating example processes in which light passing through a display apparatus is reflected according to various embodiments.

Referring to FIG. 4, the emission layer 40, the second electrode layer 50, and the anti-reflection layer 60 may each have a predetermined (e.g., specified) refractive index.

The anti-reflection layer 60 may have a first refractive index n1.

The second electrode layer 50 may have a second refractive index n2.

The emission layer 40 may have a third refractive index n3, which is the refractive index of the adhesive film 42.

The anti-reflection layer 60 may have a first thickness d1 in the vertical direction (Y direction) of the substrate 20.

The second electrode layer 50 may have a second thickness d2 in the vertical direction (Y direction) of the substrate 20.

The second electrode layer 50 may include the transparent electrode 51 as described above. Although the transparent electrode 51 has high transmittance, its transparency may lead to a high reflectance, which may lower black visibility when viewing display apparatus 1 from the outside.

For example, light reflected from the upper surface of the transparent electrode 51 and light reflected from the lower surface of the transparent electrode 51 may interfere constructively, causing strong reflection of a specific wavelength of light, which may be perceived as a specific color.

Hereinafter, an example is described in which constructive interference of specific wavelengths of light caused by the transparent electrode 51 is suppressed to improve black visibility.

When light is incident from the outside, the light may be reflected as light \textcircled{1} reflected from the upper surface of the anti-reflection layer 60, light \textcircled{2} reflected from the upper surface of the second electrode layer 50, and light \textcircled{3} reflected from the upper surface of the emission layer 40.

Even in a case where the constructive interference condition due to the second electrode layer 50 is satisfied and light \textcircled{2} and light \textcircled{3} reflected from the upper surfaces of the second electrode layer 50 and the emission layer 40 interfere constructively, when the destructive interference condition due to the anti-reflection layer 60 is satisfied, the constructively interfered light may undergo destructive interference with light \textcircled{1} reflected from the upper surface of the anti-reflection layer 60, thereby preventing/reducing strong reflection of a specific wavelength of light.

The constructive interference condition due to the second electrode layer 50 may follow Equation 1 below, because when the second refractive index n2 of the second electrode layer 50 is greater than the first refractive index n1 of the anti-reflection layer 60, fixed-end reflection occurs at the upper surface of the second electrode layer 50 with a 180° phase shift, and when the second refractive index n2 is greater than the third refractive index n3 of the emission layer 40, free-end reflection occurs at the upper surface of the emission layer 40 without a phase shift.

$$λ = \frac{2 {n}_{2} {d}_{2}}{( {m}_{1} - \frac{1}{2} )} \qquad [ Equation 1 ]$$

(λ is the wavelength of light that undergoes constructive interference depending on the second thickness d2 of the second electrode layer 50, n2 is the second refractive index, d2 is the second thickness of the second electrode layer 50, and m1 is 1, 2, or 3.)

Here, m1 may be a natural number such that the wavelength λ that causes constructive interference according to the second refractive index n2 and the second thickness d2 of the second electrode layer 50 falls within the visible light range (e.g., 380 nm to 780 nm).

For example, in a case where the second refractive index n2 is 1.858 and the second thickness d2 of the second electrode layer 50 is in the range of 60 nm to 400 nm, m1 may be 1, 2, or 3 such that the wavelength A where constructive interference due to the second electrode layer 50 occurs falls within the visible light range (e.g., 380 nm to 780 nm).

The destructive interference condition due to the anti-reflection layer 60 may follow Equation 2, because when the first refractive index n1 of the anti-reflection layer 60 is greater than an external refractive index (e.g., n0=1), fixed-end reflection occurs at the upper surface of the anti-reflection layer 60 with a 180° phase shift.

$$λ = \frac{2 {n}_{1} {d}_{1}}{( {m}_{2} - \frac{1}{2} )} \qquad [ Equation 2 ]$$

(λ is the wavelength of light that undergoes constructive interference depending on the second thickness d2 of the second electrode layer 50, n1 is the first refractive index, d1 is the first thickness of the anti-reflection layer 60, and m2 is 1.)

Here, m2 may be 1, which minimizes/reduces the first thickness d1 of the anti-reflection layer 60.

Summarizing Equations 1 and 2, the first thickness d1 of the anti-reflection layer 60 may be determined according to Equation 3.

$${d}_{1} = \frac{{n}_{2} {d}_{2}}{2 {n}_{1} ( {m}_{1} - \frac{1}{2} )} \qquad [ Equation 3 ]$$

(d1 is the first thickness of the anti-reflection layer 60, n2 is the second refractive index, d2 is the second thickness of the second electrode layer 50, n1 is the first refractive index of the anti-reflection layer 60, and m1 is 1, 2, or 3.)

The above equations (Equations 1, 2, and 3) may be based on the assumption that incident light from the outside is perpendicular. Therefore, the equations may be defined differently depending on the incident angle of the external light.

Referring to FIG. 5, the first thickness d1 of the anti-reflection layer 60 may be determined according to Equation 4.

$${d}_{1} = \frac{{n}_{2} {d}_{2}}{2 {n}_{1} {m}_{1}} \qquad [ Equation 4 ]$$

(d1 is the first thickness of the anti-reflection layer 60, n2 is the second refractive index, d2 is the second thickness of the second electrode layer 50, n1 is the first refractive index of the anti-reflection layer 60, and m1 is 1, 2, or 3.)

For example, in a case where the third refractive index n3 of the emission layer 40 is greater than the second thickness d2 of the second electrode layer 50, fixed-end reflection occurs at the upper surface of the emission layer 40 with a 180° phase shift. In this case, the first thickness d1 of the anti-reflection layer 60 may be determined according to Equation 4.

In an embodiment, the first thickness d1 of the anti-reflection layer 60 may be determined based on the first refractive index n1 of the anti-reflection layer 60, the second thickness d2 of the second electrode layer 50, and the second refractive index n2 of the second electrode layer 50.

For example, the first thickness d1 of the anti-reflection layer 60 may be determined based on the above Equation 3 or Equation 4.

The first thickness d1 of the anti-reflection layer 60 according to the disclosure may be determined not only by Equations 3 or 4, but also according to various embodiments.

For example, the first thickness d1 of the anti-reflection layer 60 may be approximately 0.5 times or 0.25 times the second thickness d2 of the second electrode layer 50.

The material of the anti-reflection layer 60 may be determined according to the second refractive index n2 of the second electrode layer 50.

For example, the material of the anti-reflection layer 60 may be selected to have a refractive index closest to the refractive index ns according to Equation 5.

$${{n}_{s}}^{2} = {n}_{0} \times {n}_{2} \qquad [ Equation 5 ]$$

(n0 is 1, and n2 is the second refractive index of the second electrode layer 50)

In a case where the second refractive index n2 of the second electrode layer 50 is 1.858, the refractive index ns according to Equation 5 may be approximately 1.363.

Accordingly, the material of the anti-reflection layer 60 may be selected to have a refractive index closest to 1.363. A more detailed description thereof will be provided below.

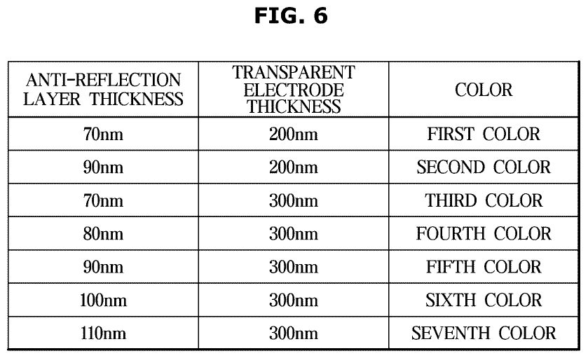

FIG. 6 is a table illustrating reflective colors of light passing through a display apparatus depending on the thicknesses of the anti-reflection layer and the transparent electrode according to various embodiments.

Referring to FIG. 6, a reflective color of the display apparatus 1 may be determined depending on the thicknesses of the anti-reflection layer 60 and the second electrode layer 50. The thickness of the second electrode layer 50 may correspond to the thickness of the transparent electrode 51.

The reflective color of the display apparatus 1 refers to the color perceived when light incident to the display apparatus 1 from the outside is reflected.

For example, when the thickness of the anti-reflection layer 60 is 70 nm and the thickness of the transparent electrode 51 is 200 nm, the reflective color of the display apparatus 1 may be perceived as a first color.

In another example, when the thickness of the anti-reflection layer 60 is 90 nm, which is different from 70 nm, and the thickness of the transparent electrode 51 is 200 nm, the reflective color of the display apparatus 1 may be perceived as a second color.

In still another example, when the thickness of the anti-reflection layer 60 is 70 nm and the thickness of the transparent electrode 51 is 300 nm, which is different from 200 nm, the reflective color of the display apparatus 1 may be perceived as a third color.

Thus, the reflective color of the display apparatus 1 perceived from the outside may vary depending on the thicknesses of the anti-reflection layer 60 and the transparent electrode 51.

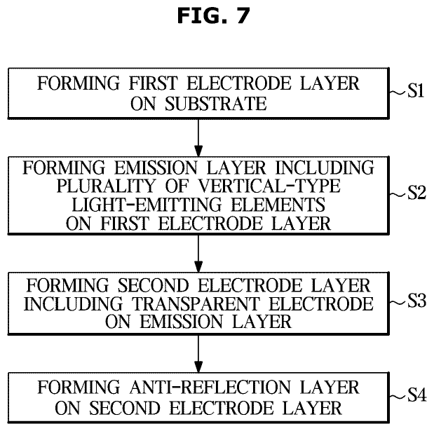

FIG. 7 is a flowchart illustrating an example method of manufacturing a display apparatus according to various embodiments.

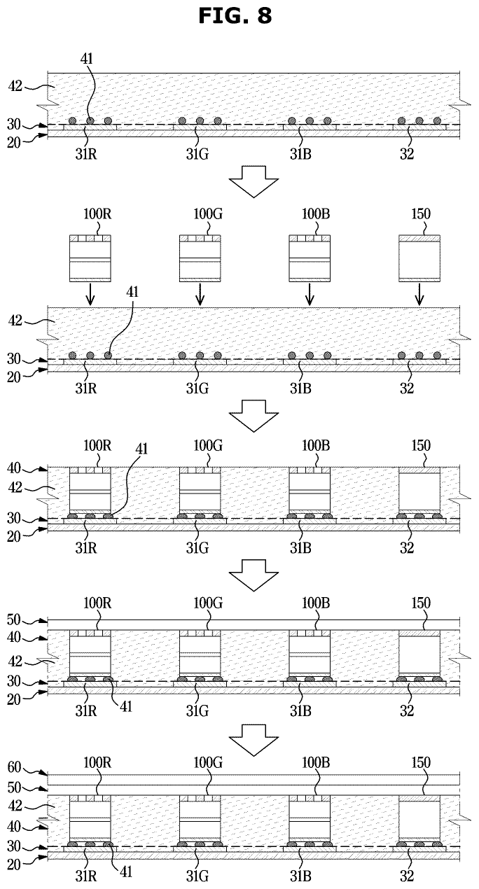

FIG. 8 is a set of cross-sectional views illustrating the example manufacturing method of the display apparatus according to various embodiments.

Referring to FIGS. 7 and 8, a method of manufacturing the display apparatus 1 according to an embodiment may include an operation (S1) of forming the first electrode layer 30 on the substrate 20.

The operation (S1) of forming the first electrode layer 30 on the substrate 20 may include an operation of forming the plurality of anodes 31R, 31G, and 31B and the cathode 32 on the substrate 20.

The operation (S1) of forming the first electrode layer 30 on the substrate 20 may also include an operation of laminating the adhesive film 42 on the substrate 20.

For example, the operation (S1) of forming the first electrode layer 30 on the substrate 20 may include an operation of applying the adhesive film 42 including conductive balls 41 on the substrate 20 in a state where the plurality of anodes 31R, 31G, and 31B and the cathode 32 are formed on the substrate 20. Accordingly, the conductive balls 41 may be disposed on the plurality of anodes 31R, 31G, and 31B and the cathode 32.

The method of manufacturing the display apparatus 1 according to an embodiment may include an operation (S2) of forming the emission layer 40 including the plurality of vertical-type light-emitting elements 100R, 100G, and 100B on the first electrode layer 30.

The operation (S2) of forming the emission layer 40 including the vertical-type light-emitting elements 100R, 100G, and 100B on the first electrode layer 30 may include an operation of attaching or transferring the vertical-type light-emitting elements 100R, 100G, and 100B and the connector 150 to the substrate 20 on which the adhesive film 42 is laminated.

Attaching the vertical-type light-emitting elements 100R, 100G, and 100B and the connector 150 to the substrate 20 on which the adhesive film 42 is laminated may include pressing an intermediate substrate (not shown), on which the vertical-type light-emitting elements 100R, 100G, and 100B and the connector 150 are transferred, against the substrate 20 on which the adhesive film 42 is laminated.

Transferring the vertical-type light-emitting elements 100R, 100G, and 100B and the connector 150 to the substrate 20 on which the adhesive film 42 is laminated may include separating the vertical-type light-emitting elements 100R, 100G, and 100B and the connector 150 from the intermediate substrate (not shown), and attaching them to the substrate 20 on which the adhesive film 42 is laminated.

Through the operation (S2), the vertical-type light-emitting elements 100R, 100G, and 100B and the connector 150 may be seated in the adhesive film 42, thereby forming the emission layer 40 including the vertical-type light-emitting elements 100R, 100G, and 100B and the connector 150.

When the operation (S2) of forming the emission layer 40 including the vertical-type light-emitting elements 100R, 100G, and 100B on the first electrode layer 30 is performed, the vertical-type light-emitting elements 100R, 100G, and 100B and the connector 150 may be electrically connected to the plurality of anodes 31R, 31G, and 31B and the cathode 32 of the first electrode layer 30 via the conductive balls 41.

The method of manufacturing the display apparatus 1 according to an embodiment may include an operation (S3) of forming the second electrode layer 50 including the transparent electrode 51 on the emission layer 40.

The operation (S3) of forming the second electrode layer 50 including the transparent electrode 51 on the emission layer 40 may include an operation of laminating the transparent electrode 51 made of Indium Tin Oxide (ITO), Indium Zinc Oxide (IZO), or nano wire paste on the emission layer 40.

When the operation (S3) of forming the second electrode layer 50 including the transparent electrode 51 on the emission layer 40 is performed, the vertical-type light-emitting elements 100R, 100G, and 100B may be electrically connected to the transparent electrode 51 via the connector 150.

The method of manufacturing the display apparatus 1 according to an embodiment may include an operation (S4) of forming the anti-reflection layer 60 on the second electrode layer 50.

The anti-reflection layer 60 may be formed of a transparent material such as silicon dioxide (SiO2), magnesium fluoride (MgF2), aluminum oxide (Al2O3), titanium dioxide (TiO2), or zirconium dioxide (ZrO2).

The operation (S4) of forming the anti-reflection layer 60 on the second electrode layer 50 may include an operation of directly stacking the anti-reflection layer 60 on the second electrode layer 50.

Directly stacking the anti-reflection layer 60 on the second electrode layer 50 may include forming the anti-reflection layer 60 on the second electrode layer 50 such that the anti-reflection layer 60 is in contact with the second electrode layer 50 without laminating another component therebetween.

The operation (S4) of forming the anti-reflection layer 60 on the second electrode layer 50 may include forming, on the second electrode layer 50, the anti-reflection layer 60 formed of a material having the first refractive index (n1, see FIG. 4) in a vertical direction with respect to the substrate 20, with the first thickness (d1, see FIG. 4). In addition, the operation (S3) of forming, on the emission layer 40, the second electrode layer 50 including the transparent electrode 51 formed of a material having the second refractive index (n2, see FIG. 4) according to an embodiment may include forming the second electrode layer 50 on the emission layer 40 in a vertical direction with respect to the substrate 20 with the second thickness (d2, see FIG. 4).

The operation (S4) of forming the anti-reflection layer 60 on the second electrode layer 50 may include determining the first thickness (d1, see FIG. 4) of the anti-reflection layer 60 based on the first refractive index n1 of the anti-reflection layer 60, the second thickness d2 of the second electrode layer 50, and the second refractive index n2 of the second electrode layer 50, and forming the anti-reflection layer 60 on the second electrode layer 50 accordingly.

The first thickness (d1, see FIG. 4) of the anti-reflection layer 60 may be determined based on the following Equation 3 or Equation 4, as described above in FIGS. 4 and 5:

$${d}_{1} = \frac{{n}_{2} {d}_{2}}{2 {n}_{1} ( {m}_{1} - \frac{1}{2} )} \qquad [ Equation 3 ]$$

(d1 is the first thickness of the anti-reflection layer 60, n2 is the second refractive index, d2 is the second thickness of the second electrode layer 50, n1 is the first refractive index of the anti-reflection layer 60, and m1 is 1, 2, or 3.)

$${d}_{1} = \frac{{n}_{2} {d}_{2}}{2 {n}_{1} {m}_{1}} \qquad [ Equation 4 ]$$

(d1 is the first thickness of the anti-reflection layer 60, n2 is the second refractive index, d2 is the second thickness of the second electrode layer 50, n1 is the first refractive index of the anti-reflection layer 60, and m1 is 1, 2, or 3.)

For example, in a case where the second refractive index n2 of the second electrode layer 50 is greater than the third refractive index n3 of the emission layer 40, the first thickness (d1, see FIG. 4) of the anti-reflection layer 60 may be determined according to the Equation 3.

In another example, in a case where the second refractive index n2 of the second electrode layer 50 is less than the third refractive index n3 of the emission layer 40, the first thickness (d1, see FIG. 4) of the anti-reflection layer 60 may be determined according to the Equation 4.

However, according to the disclosure, the determination of the first thickness (d1, see FIG. 4) of the anti-reflection layer 60 is not limited to Equations 3 or 4 and may be determined according to various methods.

For example, the first thickness d1 of the anti-reflection layer 60 may be determined to be approximately 0.5 times or 0.25 times the second thickness d2 of the second electrode layer 50.

The operation (S4) of forming the anti-reflection layer 60 on the second electrode layer 50 according to an embodiment may include an operation of determining the material of the anti-reflection layer 60 based on the second refractive index (n2, see FIG. 4) of the second electrode layer 50.

The operation of determining the material of the anti-reflection layer 60 based on the second refractive index (n2, see FIG. 4) of the second electrode layer 50 may include determining the material of the anti-reflection layer 60 such that the material of the anti-reflection layer 60 has a refractive index which is close to a predetermined value determined according to the second refractive index (n2, see FIG. 4) of the second electrode layer 50.

For example, the operation (S4) of forming the anti-reflection layer 60 on the second electrode layer 50 may include determining the anti-reflection layer 60 to be made of a material having a refractive index closest to the refractive index ns according to the following Equation 5, as described in FIGS. 4 and 5.

$${{n}_{s}}^{2} = {n}_{0} \times {n}_{2} \qquad [ Equation 5 ]$$

(n0 is 1, and n2 is the second refractive index of the second electrode layer 50)

In a case where the second refractive index n2 of the second electrode layer 50 is 1.858, the refractive index ns according to the Equation 5 may be approximately 1.363.

Accordingly, the operation (S4) of forming the anti-reflection layer 60 on the second electrode layer 50 may include forming the anti-reflection layer 60 using a material having a refractive index closest to 1.363.

According to the disclosure, by forming the anti-reflection layer 60 on the second electrode layer 50 including the transparent electrode 51, the light reflected from external incident light may be reduced.

According to the disclosure, by determining the first thickness (d1, see FIG. 4) of the anti-reflection layer 60 to be a thickness that may minimize and/or reduce interference caused by the second electrode layer 50 including the transparent electrode 51 and forming the anti-reflection layer 60 on the second electrode layer 50, the black visibility of the display apparatus 1 may be improved.

Hereinafter, a method of manufacturing the display apparatus 1 that may implement various reflective colors according to the disclosure will be described in greater detail.

Referring again to FIG. 6, in various embodiments, the method may include selecting the second thickness d2 (see FIG. 4) of the second electrode layer 50 including the transparent electrode 51 and the first thickness d1 (see FIG. 4) of the anti-reflection layer 60 to implement various reflective colors of the display apparatus 1.

In an embodiment, the method may include selecting the thickness of the anti-reflection layer 60 to be the first thickness and the thickness of the second electrode layer 50 to be the second thickness to implement a first color as a reflective color of the display apparatus 1. In addition, the method may include selecting the thickness of the anti-reflection layer 60 to the first thickness and the thickness of the second electrode layer 50 to be the third thickness different from the second thickness to implement a second color different from the first color as a reflective color of the display apparatus 1.

For example, the method may include selecting the thickness of the anti-reflection layer 60 to be 70 nm and the thickness of the transparent electrode 51 to be 200 nm to implement a first color as a reflective color of the display apparatus 1, and include selecting the thickness of the anti-reflection layer 60 to be 70 nm and the thickness of the transparent electrode 51 to be 300 nm to implement a third color as a reflective color of the display apparatus 1.

In an embodiment, the method may include selecting the thickness of the anti-reflection layer 60 to be the first thickness and the second electrode layer 50 to be the second thickness to implement a first color as a reflective color of the display apparatus 1. The method may include selecting the thickness of the anti-reflection layer 60 to be the third thickness different from the first thickness and selecting the thickness of the second electrode layer to be the second thickness to implement a second color different from the first color as a reflective color of the display apparatus 1.

For example, the method may include selecting the thickness of the anti-reflection layer 60 to be 70 nm and the thickness of the transparent electrode 51 to be 200 nm to implement a first color as a reflective color of the display apparatus 1, and include selecting the thickness of the anti-reflection layer 60 to be 90 nm and the thickness of the transparent electrode 51 to be 200 nm to implement a second color as a reflective color of the display apparatus 1.

In an embodiment, the method may include selecting the thickness of the anti-reflection layer 60 to be the first thickness and the thickness of the second electrode layer 50 to be the second thickness to implement a first color as a reflective color of the display apparatus 1. The method may include selecting the thickness of the anti-reflection layer 60 to be the third thickness different from the first thickness, and the thickness of the second electrode layer 50 to be a fourth thickness different from the second thickness to implement a second color different from the first color as a reflective color of the display apparatus 1.

For example, the method may include selecting the thickness of the anti-reflection layer 60 to be 70 nm and the thickness of the transparent electrode 51 to be 200 nm to implement a first color as a reflective color of the display apparatus 1, and include selecting the thickness of the anti-reflection layer 60 to be 80 nm and the thickness of the transparent electrode 51 to be 300 nm to implement a fourth color as a reflective color of the display apparatus 1.

According to the disclosure, various reflective colors of the display apparatus 1 may be implemented by selecting the thicknesses of the anti-reflection layer 60 and the thicknesses of the second electrode layer 50 including the transparent electrode 51.

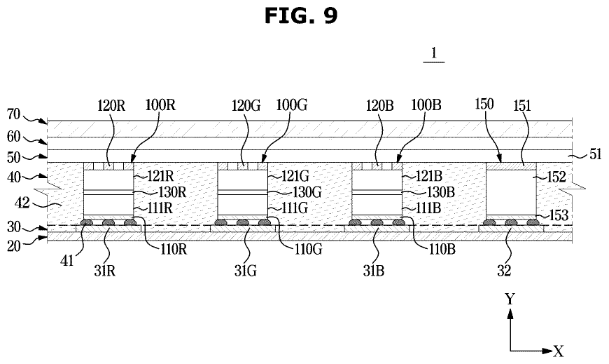

FIG. 9 is an enlarged cross-sectional view showing a side of a display apparatus according to various embodiments.

Referring to FIG. 9, the method of manufacturing the display apparatus 1 according to an embodiment may include an operation of forming an optical film 70 on the anti-reflection layer 60.

The optical film 70 may firmly fix the anti-reflection layer 60 and the second electrode layer 50.

The optical film 70 may be formed of a material that may prevent and/or reduce corrosion of the anti-reflection layer 60 and the second electrode layer 50.

The optical film 70 may be in the form of an Optically Clear Adhesive (OCA) or Optically Clear Resin (OCR) film.

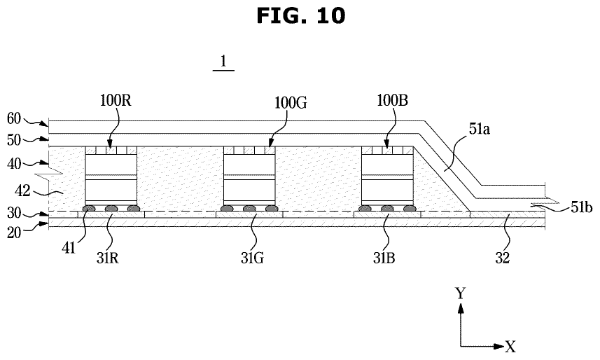

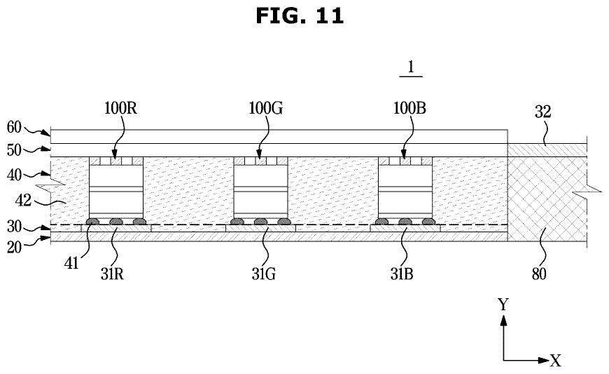

FIGS. 10 and 11 are cross-sectional views illustrating examples in which the transparent electrode is in electrical contact with the cathode according to various embodiments.

Referring to FIGS. 10 and 11, the transparent electrode 51 and the cathode 32 according to an embodiment may be in electrical contact with each other.

Referring to FIG. 10, the transparent electrode 51 may be in electrical contact with the cathode 32 formed on the substrate 20.

For example, the transparent electrode 51 may have an inclined shape (e.g., 51a of FIG. 10) toward the substrate 20. The transparent electrode 51 may also have a region (e.g., 51b of FIG. 10) that electrically contacts with the cathode 32 formed on the substrate 20.

Through the inclined shape 51a of the transparent electrode 51 toward the substrate 20 and the region 51b contacting the cathode 32 formed on the substrate 20, the transparent electrode 51 of the second electrode layer 50 may be in electrical contact with the cathode 32 on the substrate 20.

Referring to FIG. 11, the cathode 32 according to an embodiment may be in electrical contact with the transparent electrode 51 provided on the second electrode layer 50.

For example, the cathode 32 may not be formed on the substrate 20, but instead be formed on a separate wiring layer 80, thereby being in electrical contact with the transparent electrode 51 provided on the second electrode layer 50. The wiring layer 80 may include a layer in which wiring for transmitting a signal for supplying a driving current to a thin-film transistor (TFT) disposed on the substrate 20 is disposed.

Referring to FIGS. 10 and 11, even without the connector 150, the transparent electrode 51 and the cathode 32 may be in electrical contact with each other in the display apparatus 1 according to the disclosure.

Although various example embodiments of the disclosure have been illustrated and described with reference to the accompanying drawings, one skilled in the art will appreciate that various modifications may be easily made without departing from the technical spirit or essential features of the disclosure. Therefore, the foregoing embodiments should be regarded as illustrative rather than limiting in all aspects. It will also be understood that any of the embodiment(s) described herein may be used in conjunction with any other embodiment(s) described herein.

What is claimed is:

1. A display apparatus comprising:
a substrate;
a first electrode layer disposed on the substrate;
a second electrode layer disposed on the first electrode layer and comprising a transparent electrode;
an emission layer disposed between the first electrode layer and the second electrode layer, and comprising a plurality of vertical-type light-emitting elements; and
an anti-reflection layer disposed on the second electrode layer.

2. The display apparatus of claim 1,
wherein the anti-reflection layer has a first thickness in a vertical direction of the substrate and has a first refractive index,
the second electrode layer has a second thickness in the vertical direction of the substrate and has a second refractive index, and
the first thickness is based on the first refractive index, the second thickness, and the second refractive index.

3. The display apparatus of claim 2, wherein the first thickness is based on Equation 1 or Equation 2:
wherein Equation 1 is:
$${d}_{1} = \frac{{n}_{2} {d}_{2}}{2 {n}_{1} ( m - \frac{1}{2} )}$$
where d₁ is the first thickness, n₁ is the first refractive index, n₂ is the second refractive index, d₂ is the second thickness, and m is 1, 2, or 3; and
Equation 2 is:
$${d}_{1} = \frac{{n}_{2} {d}_{2}}{2 {n}_{1} m}$$
where d₁ is the first thickness, n₁ is the first refractive index, n₂ is the second refractive index, d₂ is the second thickness, and m is 1, 2, or 3.

4. The display apparatus of claim 3, wherein, based on a refractive index of the emission layer being less than the second refractive index, the first thickness is based on Equation 1.

5. The display apparatus of claim 3, wherein, based on a refractive index of the emission layer being greater than the second refractive index, the first thickness is based on Equation 2.

6. The display apparatus of claim 1, wherein the anti-reflection layer is directly stacked on the second electrode layer.

7. The display apparatus of claim 1,
wherein the emission layer further comprises a connector configured to electrically connect the transparent electrode and the first electrode layer,
the first electrode layer comprises at least one anode in electrical contact with a first electrode of each of the plurality of vertical-type light-emitting elements and at least one cathode in electrical contact with the connector, and
the transparent electrode is in electrical contact with a second electrode of each of the plurality of vertical-type light-emitting elements.

8. The display apparatus of claim 7, wherein the connector comprises a first connector electrode in electrical contact with the transparent electrode and a second connector electrode in electrical contact with the at least one cathode.

9. A method of manufacturing a display apparatus, the method comprising:
forming a first electrode layer on a substrate;
forming an emission layer on the first electrode layer, the emission layer comprising a plurality of vertical-type light-emitting elements;
forming a second electrode layer on the emission layer, the second electrode layer comprising a transparent electrode; and
forming an anti-reflection layer on the second electrode layer.

10. The method of claim 9,
wherein the forming of the anti-reflection layer on the second electrode layer comprises forming the anti-reflection layer to have a first thickness in a vertical direction of the substrate,
the forming of the second electrode layer on the emission layer comprises forming the second electrode layer to have a second thickness in the vertical direction of the substrate,
the anti-reflection layer has a first refractive index,
the second electrode layer has a second refractive index, and
the first thickness is determined based on the first refractive index, the second thickness, and the second refractive index.

11. The method of claim 10, wherein the first thickness is determined based on Equation 1 or Equation 2 below, wherein
Equation 1 is:
$${d}_{1} = \frac{{n}_{2} {d}_{2}}{2 {n}_{1} ( m - \frac{1}{2} )}$$
where d₁ is the first thickness, n₁ is the first refractive index, n₂ is the second refractive index, d₂ is the second thickness, and m is 1, 2, or 3; and
Equation 2 is:
$${d}_{1} = \frac{{n}_{2} {d}_{2}}{2 {n}_{1} m}$$
where d₁ is the first thickness, n₁ is the first refractive index, n₂ is the second refractive index, d₂ is the second thickness, and m is 1, 2, or 3.

12. The method of claim 11, wherein, based on a refractive index of the emission layer being less than the second refractive index, the first thickness is determined based on Equation 1.

13. The method of claim 11, wherein, based on a refractive index of the emission layer being greater than the second refractive index, the first thickness is determined based on Equation 2.

14. The method of claim 9, wherein the forming of the second electrode layer on the emission layer and the forming of the anti-reflection layer on the second electrode layer comprise:
selecting a thickness of the anti-reflection layer as a first thickness and a thickness of the second electrode layer as a second thickness to implement a first color as a reflective color of the display apparatus; and
selecting the thickness of the anti-reflection layer as the first thickness and the thickness of the second electrode layer as a third thickness, different from the second thickness, to implement a second color different from the first color as the reflective color of the display apparatus.

15. The method of claim 9, wherein the forming of the second electrode layer on the emission layer and the forming of the anti-reflection layer on the second electrode layer comprise:
selecting a thickness of the anti-reflection layer as a first thickness and a thickness of the second electrode layer as a second thickness to implement a first color as a reflective color of the display apparatus; and
selecting the thickness of the anti-reflection layer as a third thickness, different from the first thickness, and the thickness of the second electrode layer as the second thickness to implement a second color different from the first color as the reflective color of the display apparatus.

16. The method of claim 9, wherein the forming of the second electrode layer on the emission layer and the forming of the anti-reflection layer on the second electrode layer comprise:
selecting a thickness of the anti-reflection layer as a first thickness and a thickness of the second electrode layer as a second thickness to implement a first color as a reflective color of the display apparatus; and selecting the thickness of the anti-reflection layer as a third thickness, different from the first thickness, and the thickness of the second electrode layer as a fourth thickness different from the second thickness to implement a second color different from the first color as the reflective color of the display apparatus.

17. The method of claim 9, wherein the forming of the anti-reflection layer on the second electrode layer comprises determining a material of the anti-reflection layer based on a refractive index of the second electrode layer.

18. The method of claim 17, wherein the determining of the material of the anti-reflection layer comprises determining the material of the anti-reflection layer to have a refractive index which having a value determined according to the refractive index of the second electrode layer.

19. The method of claim 9, wherein the forming of the first electrode layer on the substrate comprises laminating an adhesive film on the substrate,
wherein the forming of the emission layer on the first electrode layer comprise attaching or transferring the plurality of vertical-type light-emitting elements and a connector to the substrate on which the adhesive film is laminated, the connector being configured to electrically connect the transparent electrode and the first electrode layer.

20. The method of claim 9, wherein the forming of the anti-reflection layer on the second electrode layer comprises directly stacking the anti-reflection layer on the second electrode layer, and
the method further comprises forming an optical film on the anti-reflection layer.
